(19) United States
(12) Patent Application Publication
(10) Pub. No.: US 2004/0075091 A1
(43) Pub. Date: Apr. 22, 2004

(54) Semiconductor package device testing apparatus

(76) Inventors: Ching-jung Huang, Hsinchu (TW); Hsiu-Chu Chou, Hsinchu (TW); Mu-Sheng Liao, Hsinchu (TW); Cheng-ji Yu, Hualien (TW); Kuo-Hsiung Hong, Hsinchu (TW)

Correspondence Address: BIRCH STEWART KOLASCH & BIRCH, PO BOX 747, FALLS CHURCH, VA, 22040-0747, US

(21) Appl. No.: 10/321,367

(22) Filed: Dec. 18, 2002

(30) Foreign Application Priority Data
Oct. 18, 2002 (TW) 091216620
Nov. 6, 2002 (CN) 02285110.0

(51) Int. Cl. H01L 23/58

(52) U.S. Cl. 257/48; 257/727

(57) ABSTRACT

A semiconductor package device testing apparatus includes a conductive component, a first main body, a second main body, a pressing member, and a heating component. The conductive component has a plurality of conductive portions electrically connect with the pins of the semiconductor package device and disposed at one side of the first main body. The second main body is disposed at the other side of the first main body. In addition, the first main body has a first opening to define a space for receiving the semiconductor package device. The semiconductor package device is disposed within the first opening by the pressing member. The pressing member connects to the second main body through a second opening of the second main body. The heating component mounts on the first main body to heat the semiconductor package device.

### BACKGROUND OF THE INVENTION

1. Field of Invention

The invention relates to a semiconductor package device testing apparatus and, more particularly, to a semiconductor package device testing apparatus applied to the manual test.

2. Related Art

In general, integrated circuit chips after being packaged have to be tested so as to ensure the qualities of the semiconductor package devices. In response to the greatly increasing throughput of the current semiconductor factory, it is a more efficient way to use an automated testing apparatus to test the semiconductor package device.

However, in some special cases, such as a product development test, minor product verification, product conductivity test, it increases manufacturing costs to purchase a set of automated testing apparatus particularly for these special cases. If the automated testing apparatus on the production line is adopted to deal with these special cases, it is necessary to stop and take up the production line. Furthermore, it is troublesome to the testers because the testers may have to run between different departments and move the set of testing apparatus such as an automated testing/sorting handler. Generally, the automated testing/sorting handler stated above can test only the semiconductor package devices of one size. In other words, several automated testing/sorting handlers are required to test the semiconductor package devices of various sizes.

Therefore, it is necessary for the testers to have a manual semiconductor package device testing apparatus. In the prior art, the tester utilizes a spring-loaded probe, such as a POGO pin, to perform a manual test for the semiconductor package device. However, after a period of time of usage, the spring-loaded probe may be oxidized and solder residues may be remained to cause poor contact, thereby causing errors in the test and adversely influencing the test result. For example, pins of a ball grid array (BGA) package device are solder balls. When the spring-loaded probe is used to test the BGA package device, the solder of the solder balls may be remained on the spring-loaded probe. As a result, the probe cannot precisely test another product owing to the poor contact.

According to the mentioned drawback, inventors studied hard to find out an improved semiconductor package device testing apparatus and filed to USPTO, wherein the filing number is 10/165,594.

However, the testing apparatus disclosed in the filed application is applied under room temperature; that is the semiconductor package device is tested under room temperature. Therefore, when high temperature is required, the disclosed testing apparatus is not suitable to test the quality of the semiconductor package device. In this case, the inventor can only use the automated testing/sorting handler to heat the semiconductor package device, to adjust the temperature of the semiconductor package device, and to test the semiconductor package device. In other words, the automated testing/sorting handler is still necessary. This would lead to increasing of costs and wasting of processing time.

To sum up, it is an important subject of the invention to provide a semiconductor package device testing apparatus, which is convenient for the tester to perform the high temperature and manual test for a semiconductor package device.

### SUMMARY OF THE INVENTION

In view of the above-mentioned problems, it is an objective of the invention to provide a semiconductor package device testing apparatus capable of performing the high temperature and manual test for a semiconductor package device.

To achieve the above-mentioned objective, the semiconductor package device testing apparatus of the invention includes a conductive component, a first main body, a second main body, a pressing member, and a heating component. In accordance with the invention, the conductive component has a plurality of conductive portions, and the first main body has a first opening. The conductive component and the second main body are disposed at two sides of the first opening of the first main body, respectively. Therefore, the space defined by the first opening may receive a semiconductor package device. The second main body has a second opening, and the pressing member is connected to the second main body through the second opening in order to position the semiconductor package device within the first opening. The heating component is connected to one side of the first main body so as to heat the semiconductor package device positioned within the first opening.

Since the testing apparatus of the invention utilizes the heating component to heat the first main body, the semiconductor package device in the first opening can be adjust to testing temperature. Therefore, the high temperature test of the semiconductor package device can be performed under manual operation.

### BRIEF DESCRIPTION OF THE DRAWINGS

The invention will become more fully understood from the detailed description given in the herein below illustration, and thus are not limitative of the present invention, and wherein:

FIG. 1 is a schematic illustration showing a load board and a semiconductor package device testing apparatus in accordance with a preferred embodiment of the invention;

FIG. 2 is a schematic illustration showing a conductive component, a first main body, a heating component, and a semiconductor package device in the semiconductor package device testing apparatus in accordance with the preferred embodiment of the invention;

FIG. 3 is a schematic illustration showing the conductive component, the first main body, the heating component, an inner frame, and the semiconductor package device in the semiconductor package device testing apparatus in accordance with the preferred embodiment of the invention;

FIG. 4 is a schematic illustration showing a second main body, a pressing member and an anvil in the semiconductor package device testing apparatus in accordance with the preferred embodiment of the invention; and

FIG. 5 is a schematic illustration showing the semiconductor package device testing apparatus in accordance with another preferred embodiment of the invention.

### DETAILED DESCRIPTION OF THE INVENTION

The semiconductor package device testing apparatus of the invention will be described with reference to the accompanying drawings, wherein the same reference numbers denote the same elements.

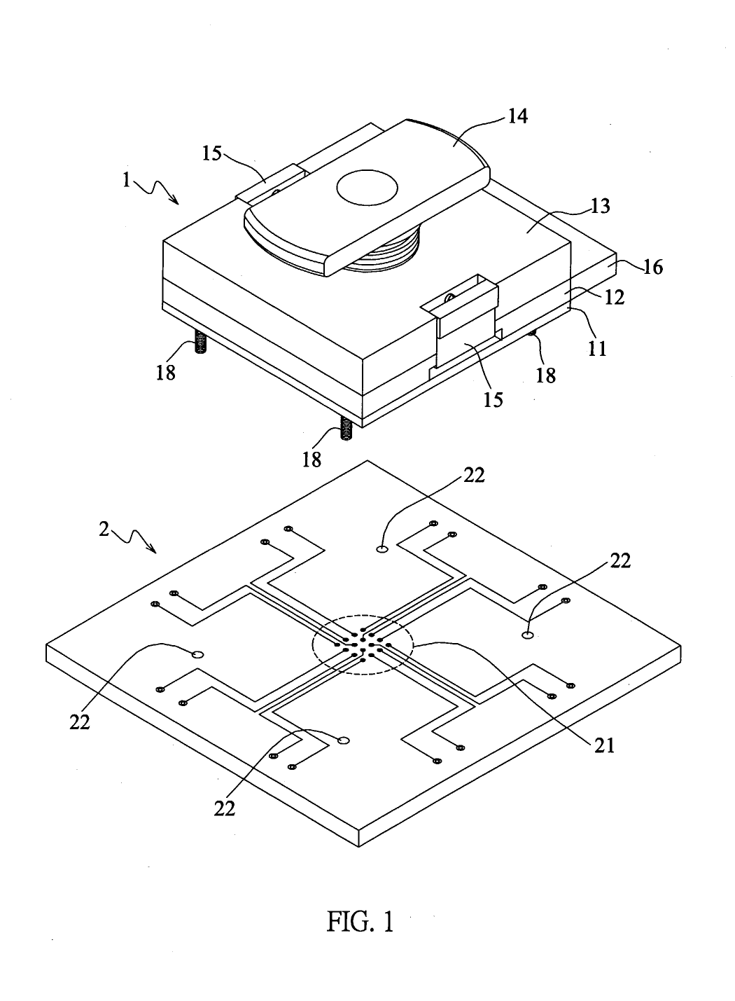

Referring to FIG. 1, a semiconductor package device testing apparatus 1 in accordance with a preferred embodiment of the invention includes a conductive component 11, a first main body 12, a second main body 13, a pressing member 14, an engagement 15, and a heating component 16.

The testing apparatus 1 tests the semiconductor package device in combination with a load board 2.

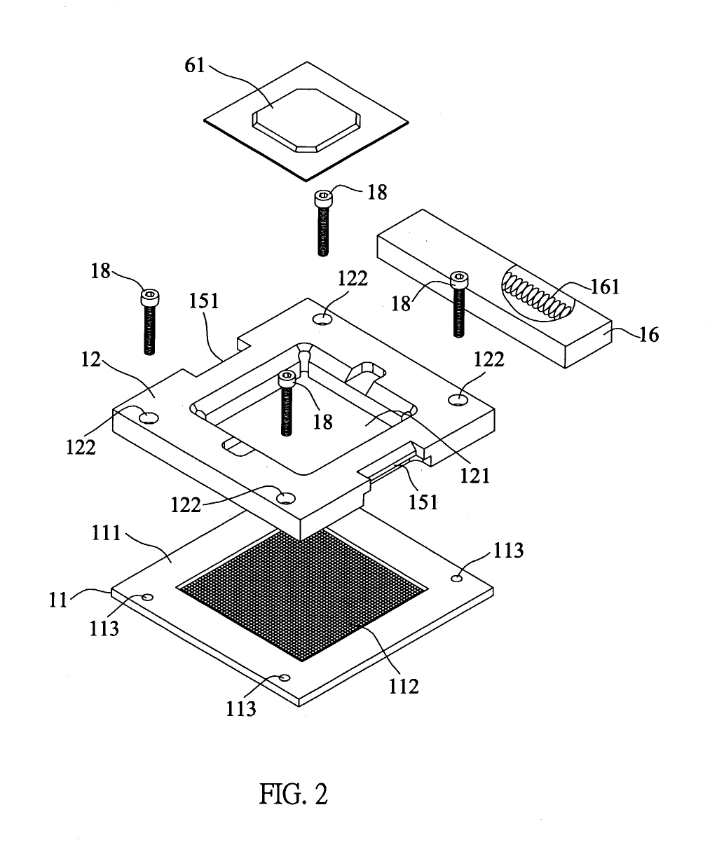

In this embodiment, the conductive component 11 includes a frame 111 and a conductive film 112. The conductive film 112 may be a flexible conductive film formed with conductive portions as shown in FIG. 2. The conductive portions are conductive points and made of a metallic material with good conductivity, such as gold. In addition, the conductive portions penetrate through the conductive film 112 and are isolated from one another.

The first main body 12 has a first opening 121 for receiving a semiconductor package device 61. As shown in FIG. 2, the size of the first opening 121 corresponds to that of the semiconductor package device 61. Therefore, the semiconductor package device 61 can be exactly received within the space defined by the first opening 121 together with the conductive component 11 and the second main body 13. In addition, when being received within the first opening 121, pins of the semiconductor package device 61 contact with the conductive film 112. For example, the semiconductor package device 61 may be a ball grid array (BGA) semiconductor package device having pins (solder balls). The pins are directed toward the conductive component 11 and electrically connected to the contact area 21 of the load board 2 via the conductive portions of the conductive film 112. In addition, the load board 2 is formed with screw holes 22. Through holes 113 and 122 are formed in the conductive component 11 and the first main body 12 at positions corresponding to the screw holes 22, respectively. Consequently, the screws 18, as shown in FIG. 2, may penetrate through the through holes 113 and 122, and match with the screw holes 22 so as to screw the conductive component 11 and the first main body 12 to the load board 2.

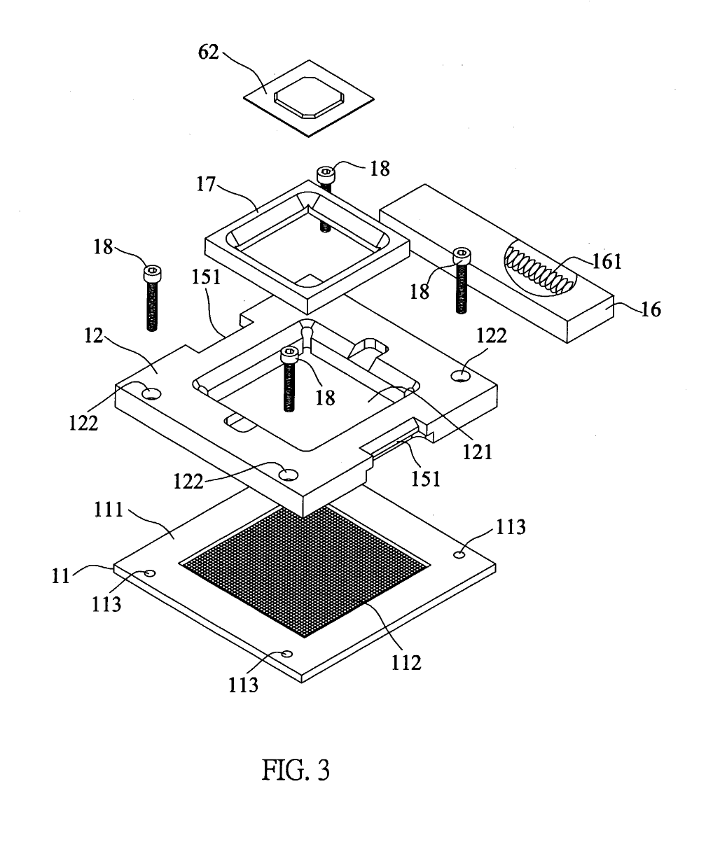

In addition, the semiconductor package device testing apparatus 1 in accordance with another embodiment of the invention may further include an inner frame 17, as shown in FIG. 3. The inner frame 17 has a shape matching with that of the first opening 121. Therefore, the inner frame 17 can be exactly received within the first opening 121. Moreover, the inner frame 17 is formed with an opening matching with the size of a semiconductor package device 62. Thus, the semiconductor package device 62 can be exactly received within the inner frame 17. As stated above, when the semiconductor package device 62 is received within the inner frame 17, the pins of the semiconductor package device 62 contact the conductive film 112 of the conductive component 11.

Comparing FIG. 2 with FIG. 3, it can be clearly understood that the size of the semiconductor package device 62 is smaller than that of the semiconductor package device 61. For example, the size of the semiconductor package device 61 may be 37.5 mm×37.5 mm, while that of the semiconductor package device 62 may be 35 mm×35 mm. In correspondence with the size of the semiconductor package device, the size of the first opening 121 is 37.5 mm×37.5 mm, and the size of the opening formed in the center of the inner frame 17 is 35 mm×35 mm. More specifically, the semiconductor package device 61 can be received within the first opening 121 for testing. When the semiconductor package device 62 is to be tested, the inner frame 17 has to be provided within the first opening 121, so that the inner frame 17 can receive the semiconductor package device 62. It is obvious to a person ordinary skilled in the art that the design of the inner frame 17 may depend upon the size of the semiconductor package device 62. For instance, the size of the semiconductor package device 62 may be 27 mm×27 mm, and that of the corresponding opening of the inner frame 17 is 27 mm×27 mm so as to receive the semiconductor package device 62. Therefore, using the design of the inner frame 17, the semiconductor package device testing apparatus of the invention can test semiconductor package devices of various sizes.

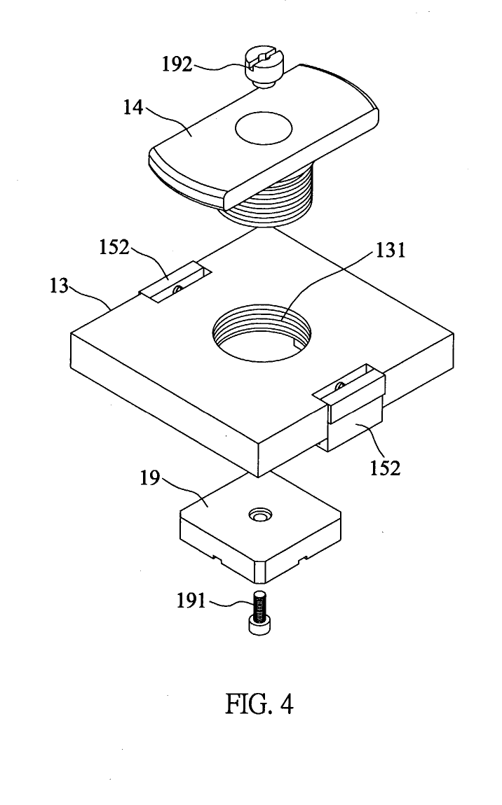

Referring again to FIG. 1, the second main body 13 is disposed on the first main body 12 and is formed with a second opening 131. The pressing member 14 is connected to the center of the second main body 13 through the second opening 131. As shown in FIG. 4, the second opening 131 is a screw hole and the pressing member 14 is screwed to the second opening 131 of the second main body 13. The semiconductor package device 61 or 62 can be pressed downward and positioned by rotating the pressing member 14.

In addition, the semiconductor package device testing apparatus 1 in accordance with the preferred embodiment of the invention may further include an anvil 19, which is connected to one end of the pressing member 14 by a fixing member. In this embodiment, the fixing member is a set of a screw 191 and a nut 192, as shown in FIG. 4. When the pressing member 14 is screwed downward, the anvil 19 can tightly press the semiconductor package device 61 or 62. Consequently, the pins of the semiconductor package device 61 or 62 may electrically connect to the contact area 21 of the load board 2 through the conductive film 112 of the conductive component 11.

Referring again to FIG. 1, the semiconductor package device testing apparatus 1 in accordance with the preferred embodiment of the invention may further include an engagement 15 for connecting the first main body 12 to the second main body 13 by way of engaging, screwing, clamping, and the like. An engaging method is described as an example in this embodiment.

Referring to FIGS. 2 to 4, the engagement 15 includes engagement portions 151 and engagement members 152. The engagement portions 151 are formed at two sides of the first main body 12 while the engagement members 152 are formed at opposite two sides of the second main body 13. Accordingly, when the second main body 13 is placed on the first main body 12, the engagement members 152 engage with the engagement portions 151, respectively. At this time, the semiconductor package device 61 or 62 may be placed within the space (i.e., the second opening 121) defined by the conductive component 11, the first main body 12, and the second main body 13.

It should be noted that although the engaging method is used as an example in this embodiment of the invention, the method for connecting the first main body 12 to the second main body 13 and the structure of the pressing member 14 are not limited thereto. It should be understood by those skilled in the art to use other ways to achieve the same object as the invention in accordance with the claims.

As stated above, semiconductor package devices can be placed within the space defined by the conductive component 11, the first main body 12 and the second main body 13. In addition, the pins of the semiconductor package device direct toward the conductive component 11, and the first main body 12 is screwed to the load board 2. Therefore, when the pressing member 14 presses the semiconductor package device downward, the pins of the semiconductor package device may be electrically connected to the contact area 21 of the load board 2 through the conductive film 112. Consequently, the tester may test the semiconductor package device on the load board 2.

Referring again to FIG. 1, the heating component 16 is connected to one side of the first main body 12, so as to heat the semiconductor package device 61 pressed by the pressing member 14 and positioned within the first opening 121. As shown in FIG. 2, the heating component 16 has a heating coil 161, so that the temperature of the heating component 16 can be increased after applying current to it. In this embodiment, the first main body 12, second main body 13, inner frame 17, and anvil 19 are thermal conductive material such as metal. Therefore, heat generated from the heating component 16 can be transferred efficiently to the semiconductor package device 61 positioned within the first opening 121. As a result, the temperature of the semiconductor package device 61 is increased accordingly.

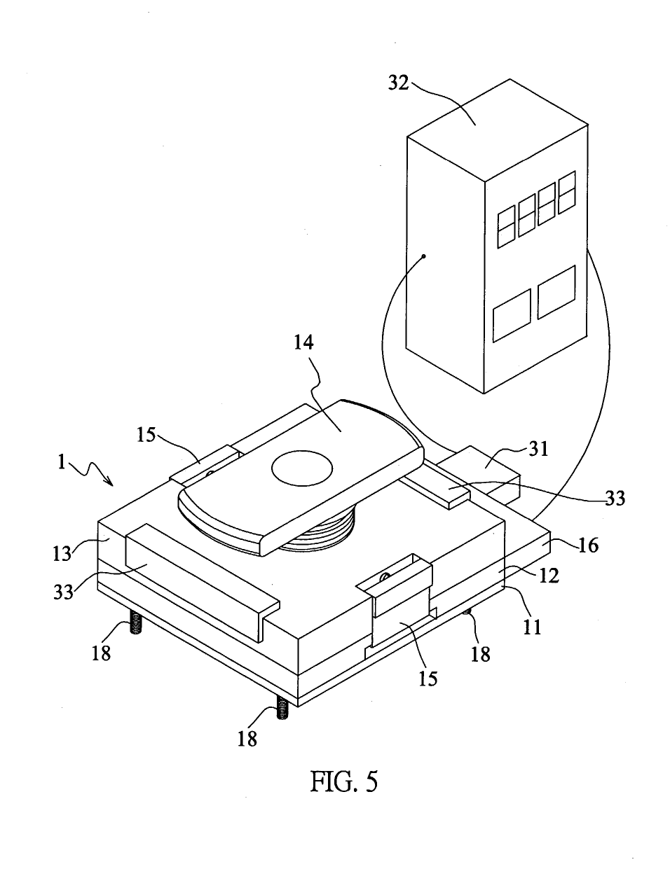

Referring to FIG. 5, another semiconductor package device testing apparatus 3 in accordance with another embodiment of the invention further includes a temperature measuring component 31 and a temperature controlling unit 32. The temperature measuring component 31 is disposed in the first main body 12. The heating component 16 and the temperature measuring component 31 are signal connected to the temperature controlling unit 32. In this embodiment, the temperature controlling unit 32 provides a calculating function and a switching function. Therefore, those skilled in this art can preset a predict value on the temperature controlling unit 32, i.e., 75° C., and then the temperature controlling unit 32 can receive the temperature measured by the temperature measuring component 31 and determine the received temperature reaches the predict value or not. When the received temperature doesn't reach the predict value, the temperature controlling unit 32 switches on the heating component 16 to heat the semiconductor package device 61.

As shown in FIG. 5, the semiconductor package device testing apparatus 3 further includes an isolation portion 33, which is mounted on the surface of the second main body 13. In this embodiment, the isolation portion 33 can be any of thermal isolating materials or low thermal conductive materials, such as plastic, wood, and the like. Therefore, when handling the testing apparatus 3, those who skilled in the art would not be burned by the high temperature.

To sum up, the semiconductor package device testing apparatus of the invention utilizes the heating component to heat the first main body, so that the semiconductor package device positioned within the first opening of the first main body can reach the desired temperature. As a result, it is possible to perform high temperature test under manual operation.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A semiconductor package device testing apparatus, comprising:
a conductive component having a plurality of conductive portions electrically connecting with pins of a semiconductor package device;
a first main body formed with a first opening, the conductive component being disposed at one side of the first opening of the first main body, and the first opening of the first main body defining a space for receiving the semiconductor package device;
a second main body formed with a second opening, the second main body being disposed at the other side of the first opening of the first main body;
a pressing member connected to the second main body through the second opening for positioning the semiconductor package device in the first opening; and
a heating component mounted on the first main body to heat the semiconductor package device positioned in the first opening.

2. The semiconductor package device testing apparatus according to claim 1, further comprising:
a engagement connecting the first main body to the second main body.

3. The semiconductor package device testing apparatus according to claim 2, wherein the engagement connects the first main body to the second main body by way of engaging.

4. The semiconductor package device testing apparatus according to claim 2, wherein the engagement connects the first main body to the second main body by way of screwing.

5. The semiconductor package device testing apparatus according to claim 2, wherein the engagement connects the first main body to the second main body by way of clamping.

6. The semiconductor package device testing apparatus according to claim 1, further comprising:
a temperature measuring component disposed in the first main body to measure temperature of the semiconductor package device.

7. The semiconductor package device testing apparatus according to claim 6, further comprising:
a temperature controlling unit receiving the temperature of the semiconductor package device measured by the temperature measuring component, and controlling the heating component to heat the semiconductor package device.

8. The semiconductor package device testing apparatus according to claim 1, further comprising:
a frame; and
a conductive film disposed within the frame, and the conductive portions are distributed in the conductive film.

9. The semiconductor package device testing apparatus according to claim 8, wherein the conductive film is a flexible conductive film.

10. The semiconductor package device testing apparatus according to claim 1, wherein the pressing member is screwed down ward in the first and second openings to press and position the semiconductor package device.

11. The semiconductor package device testing apparatus according to claim 1, further comprising:
an anvil connected to one end of the pressing member to press the semiconductor package device.

12. The semiconductor package device testing apparatus according to claim 11, wherein the anvil comprises a fixing unit for connecting the anvil to the pressing member.

13. The semiconductor package device testing apparatus according to claim 1, wherein the testing apparatus is screwed to a load board, and the conductive portions connect the pins of the semiconductor package device to a contact area of the load board.

14. The semiconductor package device testing apparatus according to claim 1, further comprising:
an inner frame placed within the first opening so as to receive another semiconductor package device having a different size.

15. The semiconductor package device testing apparatus according to claim 14, wherein the pressing member positions the semiconductor package device within the inner frame.

16. The semiconductor package device testing apparatus according to claim 1, further comprising:
an isolation portion mounted on the surface of the second main body.
